(19) United States
(12) Patent Application Publication
(10) Pub. No.: US 2009/0101069 A1
(43) Pub. Date: Apr. 23, 2009

(54) RF RETURN PLATES FOR BACKING PLATE SUPPORT

(76) Inventors: SUHAIL ANWAR, San Jose, CA (US); Robin L. Tiner, Santa Cruz, CA (US); John M. White, Hayward, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/248,869

(22) Filed: Oct. 9, 2008

Related U.S. Application Data
(60) Provisional application No. 60/979,709, filed on Oct. 12, 2007.

(51) Int. Cl. C23C 16/505

(52) U.S. Cl. 118/723 E

(57) ABSTRACT

Embodiments of the present invention generally comprise an RF return plate for use in an apparatus that utilizes RF current. Whenever a backing plate is so large that a backing plate support structure is needed to prevent the backing plate from sagging, RF current that flows across the backing plate towards the showerhead may be partially diverted and flow up the support structure. The RF current that flows up the support structure puts an unwanted bias on the support structure and also contributes to reduction of the RF current flowing to the showerhead. By returning the RF current to the source, the amount of RF current that may flow up the support structure may be reduced. An RF return plate may be disposed between the chamber lid and the support structure to redirect any RF current that may flow up the support structure back down to the chamber lid.

### CROSS-REFERENCE TO RELATED APPLICATIONS

This application claims benefit of U.S. Provisional Patent Application Ser. No. 60/979,709 (APPM/012880L), filed Oct. 12, 2007, which is herein incorporated by reference.

### BACKGROUND OF THE INVENTION

1. Field of the Invention

Embodiments of the present invention generally relate to a method and an apparatus for providing an RF return path for a backing plate support structure in an apparatus that utilizes RF current.

2. Description of the Related Art

As the demand for larger flat panel displays and solar panels increases, so must the size of the substrate to be processed. For example, a large area substrate may exceed 2 square meters in surface area. To process these large area substrates, chamber size must also increase. For a plasma enhanced chemical vapor deposition (PECVD) chamber, the backing plate is naturally going to be at least as large as the large area substrate. Hence, in a PECVD apparatus for processing large area substrates, the backing plate may exceed 2 square meters in surface area. With an increase in backing plate size, an increase in RF current is sometimes necessary if processing results are to be consistent between chambers of unequal size.

In PECVD, process gases may be introduced into the process chamber through a showerhead and ignited into a plasma by an RF current applied to the showerhead. As substrate sizes increase, the RF current applied to the showerhead may also correspondingly increase. The larger the RF current applied, the greater the danger to the technician.

Therefore, there is a need control the RF current to ensure the technician remains safe.

### SUMMARY OF THE INVENTION

Embodiments of the present invention generally comprise an RF return plate for use in an apparatus that utilizes RF current. Whenever a backing plate is so large that a backing plate support structure is needed to prevent the backing plate from sagging, RF current that flows across the backing plate towards the showerhead may be partially diverted and flow up the support structure. The RF current that flows up the support structure puts an unwanted bias on the support structure and also contributes to reduction of the RF current flowing to the showerhead. By returning the RF current to the source, the amount of RF current that may flow up the support structure may be reduced. An RF return plate may be disposed between the chamber lid and the support structure to redirect any RF current that may flow up the support structure back down to the chamber lid.

In one embodiment, an apparatus comprises a chamber lid, a backing plate, a backing plate support structure coupled with the chamber lid, and an RF return plate coupled with the one or more fastening mechanisms and the chamber lid. The backing plate support structure spanning across the chamber lid and coupled with the backing plate at a substantial center of the backing plate. The backing plate support structure also coupled with the chamber lid with one or more fastening mechanisms.

In another embodiment an apparatus includes a chamber lid, a support structure coupled with a plurality of edges of the chamber lid and extending above the chamber lid, a coupling element extending down from the support structure and supported by the support structure from above, and an RF return plate coupled between the coupling element and the chamber lid. The support structure extends across the chamber lid at a location above the chamber lid.

In another embodiment, an apparatus comprises an RF return plate body having one or more channels therethrough sized to receive one or more first fastening mechanisms that secure a backing plate to a backing plate support structure and having one or more second channels therethrough sized to receive a fastening mechanism to couple the RF return plate body to a chamber lid.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a PECVD apparatus according to one embodiment of the invention.

FIG. 2 is a top perspective view of a chamber lid and support assembly according to one embodiment of the invention.

FIG. 3 is a cross sectional view of a chamber lid section of a PECVD apparatus according to one embodiment of the invention.

FIG. 4A is a top view of the support ring according to one embodiment of the invention.

FIG. 4B is a cut away view of the bolts through the backing plate and support ring of FIG. 4A.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally comprise an RF return plate for use in an apparatus that utilizes RF current. Whenever a backing plate is so large that a backing plate support structure is needed to prevent the backing plate from sagging, RF current that flows across the backing plate towards the showerhead may be partially diverted and flow up the support structure. The RF current that flows up the support structure puts an unwanted bias on the support structure and also contributes to reduction of the RF current flowing to the showerhead. By returning the RF current to the source, the amount of RF current that may flow up the support structure may be reduced. An RF return plate may be disposed between the chamber lid and the support structure to redirect any RF current that may flow up the support structure back down to the chamber lid. It is understood that the substrate to be processed may be any suitable substrate such as a semiconductor substrate, a flat panel display substrate, a solar panel substrate, etc.

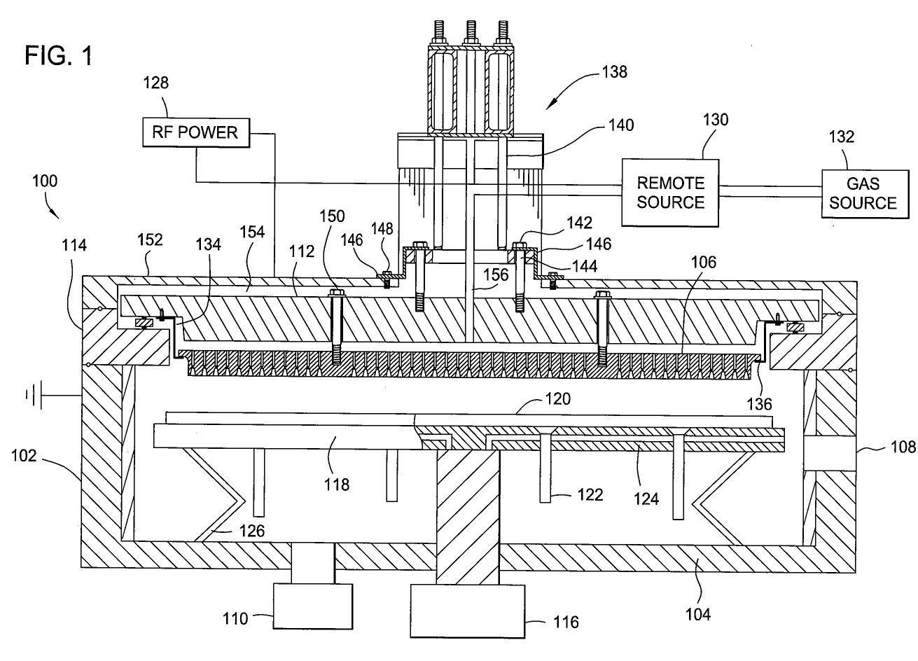

FIG. 1 is a cross sectional view of a PECVD apparatus according to one embodiment of the invention. The apparatus includes a chamber 100 in which one or more films may be deposited onto a substrate 120. One suitable PECVD apparatus which may be used is available from Applied Materials, Inc., located in Santa Clara, Calif. While the description below will be made in reference to a PECVD apparatus, it is to be understood that the invention is equally applicable to other processing chambers as well, including those made by other manufacturers.

The chamber 100 generally includes walls 102, a bottom 104, a showerhead 106, and substrate support 118 which define a process volume. The process volume is accessed through a slit valve opening 108 such that the substrate 120 may be transferred in and out of the chamber 100. The substrate support 118 may be coupled to an actuator 116 to raise and lower the substrate support 118. Lift pins 122 are moveably disposed through the substrate support 118 to move a substrate to and from the substrate receiving surface. The substrate support 118 may also include heating and/or cooling elements 124 to maintain the substrate support 118 at a desired temperature. The substrate support 118 may also include RF return straps 126 to provide an RF return path at the periphery of the substrate support 118.

The showerhead 106 is coupled to a backing plate 112 by a fastening mechanism 150. The showerhead 106 may be coupled to the backing plate 112 by one or more fastening mechanism 150 to help prevent sag and/or control the straightness/curvature of the showerhead 106. In one embodiment, twelve fastening mechanisms 150 may be used to couple the showerhead 106 to the backing plate 112. The fastening mechanisms 150 may include a nut and bolt assembly. In one embodiment, the nut and bolt assembly may be made with an electrically insulating material. In another embodiment, the bolt may be made of a metal and surrounded by an electrically insulating material. In still another embodiment, the showerhead 106 may be threaded to receive the bolt. In yet another embodiment, the nut may be formed of an electrically insulating material. The electrically insulating material helps to prevent the fastening mechanisms 150 from becoming electrically coupled to any plasma that may be present in the chamber 100.

A gas source 132 is coupled to the backing plate 112 to provide gas through gas passages in the showerhead 106 to the substrate 120. A vacuum pump 110 is coupled to the chamber 100 to control the process volume 106 at a desired pressure. A RF power source 128 is coupled to the backing plate 112 and/or to the showerhead 106 to provide a RF current to the showerhead 106. The RF current creates an electric field between the showerhead 106 and the substrate support 118 so that a plasma may be generated from the gases between the showerhead 106 and the substrate support 118. Various frequencies may be used, such as a frequency between about 0.3 MHz and about 200 MHz. In one embodiment, the RF current is provided at a frequency of 13.56 MHz.

A remote plasma source 130, such as an inductively coupled remote plasma source 130, may also be coupled between the gas source 132 and the backing plate 112. Between processing substrates, a cleaning gas may be provided to the remote plasma source 130 so that a remote plasma is generated. The radicals from the remote plasma may be provided to chamber 100 to clean chamber 100 components. The cleaning gas may be further excited by the RF power source 128 provided to the showerhead 106. Suitable cleaning gases include but are not limited to NF₃, F₂, and SF₆. The spacing between the top surface of the substrate 120 and the showerhead 106 may be between about 400 mil and about 1,200 mil. In one embodiment, the spacing may be between about 400 mil and about 800 mil.

The backing plate 112 may be supported by a support assembly 138. One or more anchor bolts 140 may extend down from the support assembly 138 to a support ring 144. The support ring 144 may be coupled with the backing plate 112 by one or more fastening mechanisms 142. In one embodiment, the fastening mechanisms 142 may comprise a nut and bolt assembly. In another embodiment, the fastening mechanisms 142 may comprise a threaded bolt coupled with a threaded receiving surface of the backing plate 112. The support ring 144 may be coupled with the backing plate 112 substantially in the center of the backing plate 112. The center of the backing plate 112 is the area of the backing plate 112 with the least amount of support in absence of the support ring 144. Therefore, supporting the center area of the backing plate 112 may reduce and/or prevent sagging of the backing plate 112. In one embodiment, the support ring 144 may be coupled to an actuator that controls the shape of the backing plate 112 so that the center of the backing plate 112 may be raised or lowered relative to the edges of the backing plate 112. The movement of the backing plate 112 may occur in response to a metric obtained during processing. In one embodiment, the metric is the thickness of the layer being deposited. In another embodiment, the metric is the composition of the layer deposited. The movement of the backing plate 112 may occur simultaneous with the processing. In one embodiment, the one or more fastening mechanisms 142 may extend through the backing plate 112 to the showerhead 106.

The showerhead 106 may additionally be coupled to the backing plate 112 by a bracket 134. The bracket 134 may have a ledge 136 upon which the showerhead 106 may rest. The backing plate 112 may rest on a ledge 114 coupled with the chamber walls 102 to seal the chamber 100. A chamber lid 152 may be coupled with the chamber walls 102 and spaced from the backing plate 112 by area 154. In one embodiment, the area 154 may comprise air. In another embodiment, the area 154 may comprise an electrically insulating material. The chamber lid 152 may have an opening therethrough to permit the one or more fastening mechanisms 142 to couple with the backing plate 112 and the gas feed conduit 156 to supply processing gas to the chamber 100. In one embodiment, the support ring 144 may be disposed below the chamber lid 152 and substantially centered within the opening of the chamber lid 152.

An RF return plate 146 may be coupled with the ring 144 and the chamber lid 152. The RF return plate 146 may be coupled with the chamber lid 152 by a fastening mechanism 148. In one embodiment, the fastening mechanism 148 comprises a lag screw. The RF return plate 146 may be coupled between the fastening mechanism 142 and the ring 144. The RF return plate 146 provides a path to the RF power source 128 for any RF current that may travel up the fastening mechanism 142 to the ring 144. The RF return plate 146 provides a path for the RF current to flow back down to the chamber lid 152 and then to the RF power source 128.

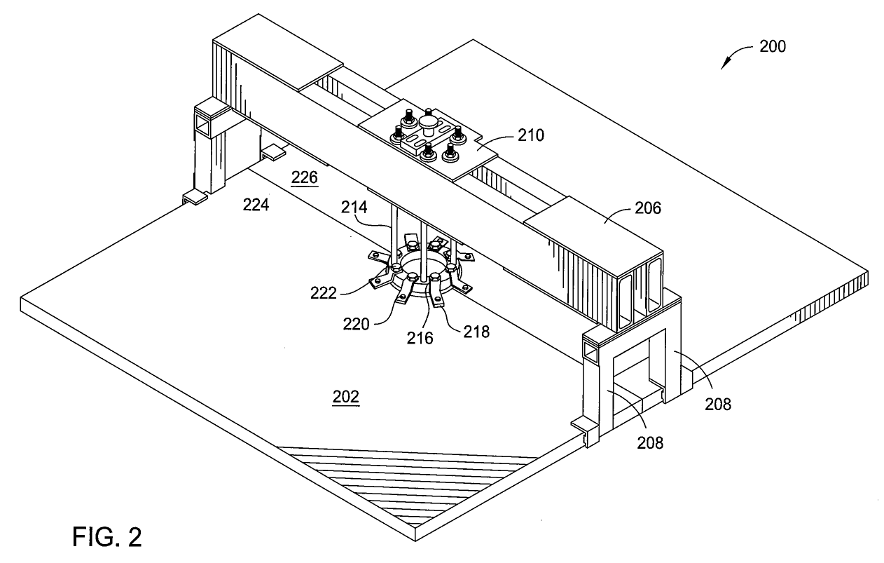

FIG. 2 is a top perspective view of a chamber lid 202 and support assembly 200 according to one embodiment of the invention. The backing plate that is below the chamber lid 202 may be center supported by a support structure 206. The support structure 206 may be coupled with the chamber lid 202 by one or more legs 208. The support structure 206 may include a lift plate 210 to permit the removal of the support structure 206. A plurality of fastening mechanisms 214 are shown for coupling the ring to the support structure 206. One or more fastening mechanisms 222 may couple the ring to the backing plate. An RF return plate 216 may be coupled to the chamber lid 202 by a fastening mechanism 218. In one embodiment, the fastening mechanism 218 may comprise a lag screw. In one embodiment, the chamber lid 202 may comprise a plurality of sections 224, 226. In another embodiment, the chamber lid 202 may comprise a single piece of material having an opening through the center thereof to permit the fastening mechanism 222 to couple the ring to the backing plate.

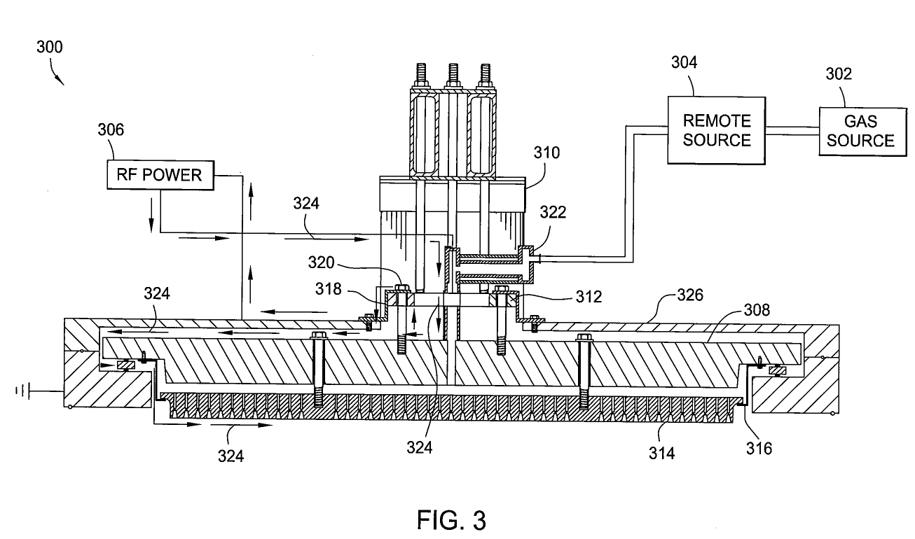

FIG. 3 is a cross sectional view of a lid section of a PECVD apparatus 300 according to one embodiment of the invention. The apparatus 300 includes a gas source 302 for introducing a processing gas into the chamber for depositing a layer onto a substrate. The gas source 302 may also introduce a cleaning gas to the remote plasma source 304 where it may be ignited into a plasma and sent to the chamber to clean the chamber. The apparatus 300 may include a support structure 310 coupled to a backing plate 308. One or more fastening mechanisms 320 may couple a ring 312 to the backing plate 308. The ring 312 may be coupled with the support structure 310. A showerhead 314 through which the processing gas may flow to encounter a substrate may be coupled to the backing plate 308 utilizing one or more fastening mechanisms disposed substantially near the center of both the backing plate 308 and the showerhead 314. The showerhead 314 may be additionally coupled with the backing plate by a bracket 316.

RF current may flow to the apparatus 300 from an RF power source 306. The RF current may flow to the processing chamber along the outside of an RF choke 322. The RF choke 322 has the processing gas flow therethrough to reach the processing chamber. The RF current passes on the outside of the RF choke 322. Coupling the gas and the RF current through a common location may, on its face, appear to be a recipe for disaster. However, RF current has a “skin effect” in traveling on conductive surfaces. RF current travels as close as possible to the source driving it. Thus, RF current travels on the surface of a conductive element and penetrates only to a certain, predeterminable depth (i.e., the skin) of the conductive element. The predeterminable depth may be calculated as a function of the maximum RF current to be applied. Thus, when a conductive element is thinner than the predetermined depth of the RF current penetration, the RF current may directly interact with the gas flowing therein. Conversely, when a conductive element is thicker than the predetermine depth of the RF current penetration, the RF current may not interact with the gas flowing therein.

The RF current will flow towards the processing chamber. As the RF current travels along the outside of the conduit leading to the backing plate 308 from the RF choke 322, the RF current, when it encounters the backing plate 308, may flow along the upper surface of the backing plate 308. The RF current may travel along the upper side of the backing plate 308, then flow down the side of the backing plate 308 until it encounters the bracket 316. The RF current then may travel along the bracket 316 until it reaches the front side of the showerhead 314. The RF path from the RF power source 306 to the front of the showerhead 314 is shown by arrows 324.

Along the upper surface of the backing plate 308, the RF current may encounter the fastening mechanisms 320 that couple the backing plate 308 to the ring 312. The RF current may travel up the fastening mechanism 320. The RF current may creep between the backing plate 308 and any insulating material insulating the backing plate 308 from the fastening mechanism 320 to reach the fastening mechanism 320. If the RF current reaches the fastening mechanism 320, the RF current may travel up the fastening mechanism 320 to the ring 312. The RF current that travels up the fastening mechanism 320 may create a danger to a technician servicing or operating the apparatus 300. Additionally, the RF current diverted from the backing plate 308 contributes to increase the inductance and may reduce the amount of RF current that reaches the showerhead 324. The smaller the amount of RF current that is diverted away from the showerhead 314, the more efficient that apparatus will be.

One or more RF return plates 318 may be coupled between the fastening mechanisms 320 and the ring 312. The RF return plate 318 may also be coupled with the chamber lid 326. The RF return plate 318 may return the RF current to the chamber lid 326. In one embodiment, the RF return plate 318 may be coupled between the fastening mechanism 320 and the ring 312 at a location above the ring 312. In another embodiment, the RF return plate 318 may be coupled between the fastening mechanism 320 and the ring 312 at a location below the ring 312. In one embodiment, the RF return plate 318 may comprise copper while the fastening mechanism 320 and the ring 312 may comprise a material having a lower electrical conductivity such as aluminum or stainless steel. Because copper has a higher electrical conductivity, the RF current may flow along the RF return plate 318 back to the chamber lid 326 rather than up the support structure 310. In one embodiment, the RF return plate 318 may have a substantially “S” shaped cross section. It is contemplated that other shapes may be utilized for the RF return plate 318. The RF current flows along the RF return plate 318 to the top surface of the lid 326 and then returns to the RF power source 306.

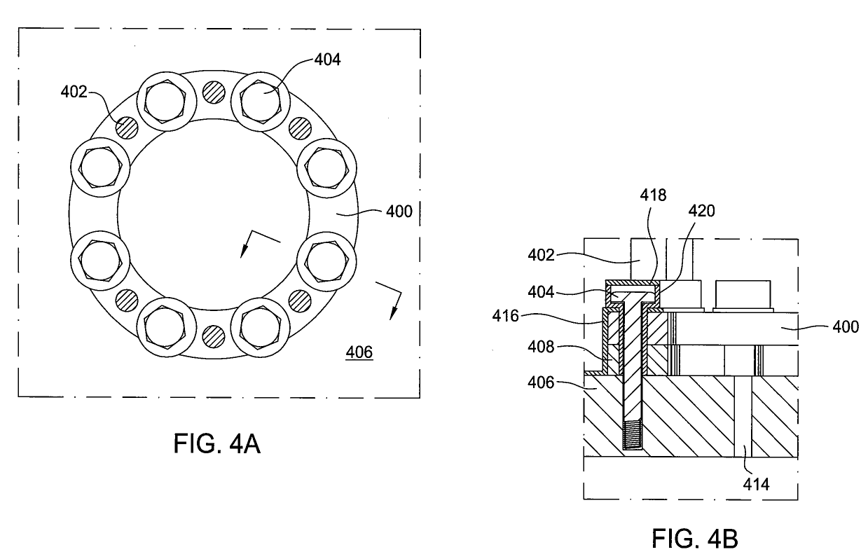

FIG. 4A is a top view of a support ring 400 coupled to a backing plate 406 according to one embodiment of the invention. In FIG. 4A, the electrically insulating material 420, the cap 418, and the RF return plate 416 are not shown for clarity. Bores 402 for coupling the ring 400 to a support structure are shown, and bolts 404 have also been shown. While bores 402 may be present, six bores 402 have been shown. It is to be understood that more or less bores 402 may be used. Additionally, while eight bolts 404 coupling the support ring 400 to the backing plate 406 are shown, it is to be understood that more or less bolts 404 may be used. FIG. 4B is a cut away view of the bolts 404 through the backing plate 406 and support ring 400 of FIG. 4A. Between the support ring 400 and the backing plate 406, the bolts 404 may be electrically isolated by an insulating washer 408. In one embodiment, the insulating washer 408 may be countersunk into the backing plate 406. Other insulating material may be present to electrically isolate the bolts from RF current. A channel 414 for passing processing gas through the backing plate 406 is shown. The bolt 404 may be enclosed in an electrically insulating material 420 that is capped with a cap 418. The bolt 404, because it is directly screwed into the backing plate 406, is RF hot and thus has current flowing along it. The RF return plate 416 can return the RF current to the lid (not shown). The RF return plate 416 may be coupled between the support ring 400 and the electrically insulating material 420. In one embodiment, the RF return plate 416 may be coupled between the bolts 404 and the bottom of the support ring 400. While the lid is not shown, the other end of the RF return plate 416 may be coupled to the lid.

By coupling an RF return plate between the backing plate support structure and the chamber lid, the amount of RF current that flows to the support structure may be reduced and the chamber may be safer for a technician to access.

While the foregoing is directed to embodiments of the present invention, other and further embodiments of the invention may be devised without departing from the basic scope thereof, and the scope thereof is determined by the claims that follow.

1. An apparatus, comprising:
a chamber lid;
a backing plate;
a backing plate support structure coupled with the chamber lid at an edge thereof, the backing plate support structure spanning across the chamber lid and coupled with the backing plate at a substantial center of the backing plate, the backing plate support structure coupled with the backing plate with one or more first fastening mechanisms that extends through the chamber lid; and
an RF return plate coupled with the backing plate support structure and the chamber lid.

2. The apparatus of claim 1, wherein the RF return plate has an “S” shaped cross section.

3. The apparatus of claim 1, wherein the apparatus is a plasma enhanced chemical vapor deposition apparatus.

4. The apparatus of claim 1, further comprising:
a support ring coupling the backing plate support structure to the backing plate.

5. The apparatus of claim 4, wherein the RF return plate is coupled to the support ring by the one or more first fastening mechanisms and the RF return plate is coupled to the chamber lid by one or more second fastening mechanisms.

6. The apparatus of claim 5, wherein the chamber lid has an opening therethrough at a substantial center thereof, and wherein the support ring has a diameter that is smaller than the diameter of the opening.

7. The apparatus of claim 1, wherein the RF return plate comprises a material having a first electrical conductivity and the backing plate support structure comprises a material having a second electrical conductivity that is less than the first electrical conductivity.

8. The apparatus of claim 1, wherein the backing plate support structure further comprises a ring, wherein the RF return plate is coupled between the one or more first fastening mechanisms and the ring.

9. The apparatus of claim 8, wherein the RF return plate is coupled between one or more second fastening mechanisms and the chamber lid.

10. The apparatus of claim 1, wherein the chamber lid comprises a plurality of pieces.

11. The apparatus of claim 1, wherein the chamber lid has an opening therethrough located at a substantial center of the chamber lid.

12. The apparatus of claim 11, wherein the one or more first fastening mechanisms extend through the opening of the chamber lid.

13. An apparatus, comprising:
a chamber lid;
a support structure coupled with a plurality of edges of the chamber lid and extending above the chamber lid, the support structure extending across the chamber lid at a location above the chamber lid;
a coupling element extending down from the support structure and supported by the support structure from above; and
an RF return plate coupled between the coupling element and the chamber lid.

14. The apparatus of claim 13, wherein the RF return plate comprises a material having a first electrical conductivity and the coupling element comprises a material having a second electrical conductivity that is less than the first electrical conductivity.

15. The apparatus of claim 13, wherein the chamber lid has an opening therethrough located at a substantial center of the chamber lid.

16. The apparatus of claim 13, wherein the RF return plate has an “S” shaped cross section.

17. The apparatus of claim 13, wherein the chamber lid comprises a plurality of pieces, and the RF return plate is coupled with at least two of the plurality of pieces.

18. An apparatus, comprising:
an RF return plate body having one or more channels therethrough sized to receive one or more first fastening mechanisms that secure a backing plate to a backing plate support structure and having one or more second channels therethrough sized to receive a fastening mechanism to couple the RF return plate body to a chamber lid.

19. The apparatus of claim 18, wherein the RF return plate body has an “S” shaped cross section.

20. The apparatus of claim 18, wherein the RF return plate body comprises copper.
